(19) United States
(12) Patent Application Publication
(10) Pub. No.: US 2025/0268061 A1
(43) Pub. Date: Aug. 21, 2025

(54) DISPLAY APPARATUS HAVING LIGHT-EMITTING DEVICES

(71) Applicant: LG Display Co., Ltd., Seoul (KR)

(72) Inventors: Seung Ryong JOUNG, Paju-si (KR); Hee Su BYEON, Paju-si (KR)

(21) Appl. No.: 18/968,657

(22) Filed: Dec. 4, 2024

(30) Foreign Application Priority Data
Feb. 15, 2024 (KR) 10-2024-0021707

(51) Int. Cl. H10K 59/80; H10K 59/32; H10K 59/38

(52) U.S. Cl. CPC H10K 59/80521; H10K 59/32; H10K 59/38; H10K 59/80515; H10K 59/873

(57) ABSTRACT

A display apparatus including light-emitting devices is provided. The light-emitting devices can overlap emission areas of a device substrate. Each of the emission areas can display a different color from adjacent emission area. Each of the light-emitting devices can have a stacked structure of a lower electrode, a light-emitting unit and an upper electrode. For example, the light-emitting unit of each light-emitting device can include an emission stack having a stacked structure of a red emission material layer and a green emission material layer. The lower electrode of at least one of the light-emitting devices can have a different resistance from the lower electrodes of adjacent light-emitting devices. Thus, in the display apparatus, the overall luminance can be improved.

### CROSS-REFERENCE TO RELATED APPLICATIONS

This application claims the benefit of Korean Patent Application No. 10-2024-0021707, filed on Feb. 15, 2024, which is hereby incorporated by reference as if fully set forth herein.

### BACKGROUND

### Technical Field

The present disclosure relates to a display apparatus in which light-emitting devices are disposed on emission areas of a device substrate.

### Description of the Related Art

Generally, a display apparatus provides an image to a user. For example, the display apparatus can include light-emitting devices. Each of the light-emitting devices can emit light displaying a specific color. For example, each of the light-emitting devices can include a light-emitting unit disposed between a lower electrode and an upper electrode. Light emitted from each light-emitting device can display a same color as light emitted from adjacent light-emitting device. For example, the light-emitting unit of each light-emitting device can generate white light.

### BRIEF SUMMARY

The light-emitting devices can be disposed on emission areas of a device substrate. Each of the emission areas can realize a different color from adjacent emission area. For example, in the display apparatus, only some of the light generated by the light-emitting device of each emission area can be emitted outside by a micro-cavity structure and/or a color filter. The inventors of the present disclosure have recognized that according to the display apparatus in the related art, there is a problem that the overall luminance of the display apparatus can be decreased. Accordingly, the present disclosure is directed to a display apparatus that substantially obviates one or more problems due to limitations and disadvantages of the related art, including the aforementioned technical problem.

Various embodiments of the present disclosure provide a display apparatus capable of improving the overall luminance.

Various embodiments of the present disclosure provide a display apparatus that the efficiency of each emission area can increased as a whole.

Additional advantages, technical benefits, and features of the disclosure will be set forth in part in the description which follows and in part will become apparent to those having ordinary skill in the art upon examination of the following or can be learned from practice of the disclosure. Other advantages of the disclosure can be realized and attained by the structure particularly pointed out in the written description and claims hereof as well as the appended drawings.

To achieve these and other advantages and in accordance with the spirit of the present disclosure, as embodied and broadly described herein, there is provided a display apparatus comprising a device substrate. A first lower electrode is disposed on a first emission area of the device substrate. A second lower electrode is disposed on a second emission area of the device substrate. The second lower electrode is spaced apart from the first lower electrode. A light-emitting unit is disposed on the first lower electrode and the second lower electrode. The light-emitting unit including a plurality of emission stacks. An upper electrode is disposed on the light-emitting unit. The upper electrode overlaps the first emission area and the second emission area. The upper electrode has a work-function lower than the first lower electrode and the second lower electrode. The plurality of emission stacks include a first emission stack having a stacked structure of a red emission material layer and a first green emission material layer. A work-function of the second lower electrode is different from a work-function of the first lower electrode.

The second lower electrode can be disposed on a different layer from the first lower electrode.

The second lower electrode can include a different material from the first lower electrode.

A resistance of the second lower electrode can be larger than a resistance of the first lower electrode.

The first emission stack can be disposed close to the first lower electrode and the second lower electrode.

The red emission material layer can be disposed between the first lower electrode and the first green emission material layer and between the second lower electrode and the first green emission material layer.

The plurality of emission stacks can include a second emission stack and a third emission stack. The second emission stack disposed between the first emission stack and the third emission stack can include a blue emission material layer. The third emission stack disposed between the second emission stack and the upper electrode can include a second green emission material layer.

The second green emission material layer can include a same dopant as the first green emission material.

A host of the second green emission material layer can include a different material from a host of the first green emission material layer.

The first green emission material layer can include a single hole transporting host.

In another embodiment, there is provided a display apparatus comprising a device substrate. A first light-emitting device is disposed on a first emission area of the device substrate. The first light-emitting device has a stacked structure of a first lower electrode, a first light-emitting unit and a first upper electrode. A second light-emitting device is disposed on a second emission area of the device substrate. The second light-emitting device has a stacked structure of a second lower electrode, a second light-emitting unit and a second upper electrode. The first light-emitting device and the second light-emitting device area covered by an encapsulation structure. Each of the first light-emitting unit and the second light-emitting unit includes an emission stack having a stacked structure of a red emission material layer and a green emission material layer. The second upper electrode of the second light-emitting device is electrically connected to the first upper electrode of the first light-emitting device. The second lower electrode of the second light-emitting device has an electrical conductivity different from the first lower electrode of the first light-emitting device.

A filter passivation layer can be disposed on the encapsulation structure. A color filter can be disposed between the encapsulation structure and the filter passivation layer. The color filter can overlap the first emission area. A portion of the filter passivation layer overlapping with the second emission area can be in contact with the encapsulation structure.

The second lower electrode can have a different thickness from the first lower electrode.

The first lower electrode can have a stacked structure of a first electrode layer and a second electrode layer. The first electrode layer can include a same material as the second lower electrode. The second electrode layer can have an electrical conductivity different from the first electrode layer.

A planar shape of the second lower electrode can be different from a planar shape of the first lower electrode.

### BRIEF DESCRIPTION OF THE SEVERAL VIEWS OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to an embodiment of the present disclosure;

FIG. 2 is a view showing a circuit of a sub-pixel in the display apparatus according to the embodiment of the present disclosure;

FIG. 3 is a view showing a cross-section of a pixel area in the display apparatus according to the embodiment of the present disclosure;

FIG. 4 is an enlarged view of K1 region and K2 region in FIG. 3;

FIG. 5 is a view showing an energy band diagram of a first emissions stack in the display apparatus according to the embodiment of the present disclosure;

FIGS. 6 and 7 are graphs showing the intensity of green color or red color in a comparison display apparatus in which the lower electrode of each emission area includes a same material and the display apparatus according to the embodiment of the present disclosure; and

FIGS. 8 to 12 are views showing the display apparatus according to another embodiment of the present disclosure.

### DETAILED DESCRIPTION

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure can be embodied in other forms and is not limited to the embodiments described below.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

It will be understood that, when a first element is referred to as being “on” a second element, although the first element can be disposed on the second element so as to come into contact with the second element, a third element can be interposed between the first element and the second element.

Here, terms such as, for example, “first” and “second” can be used to distinguish any one element with another element. However, the first element and the second element can be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” can include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### Embodiment

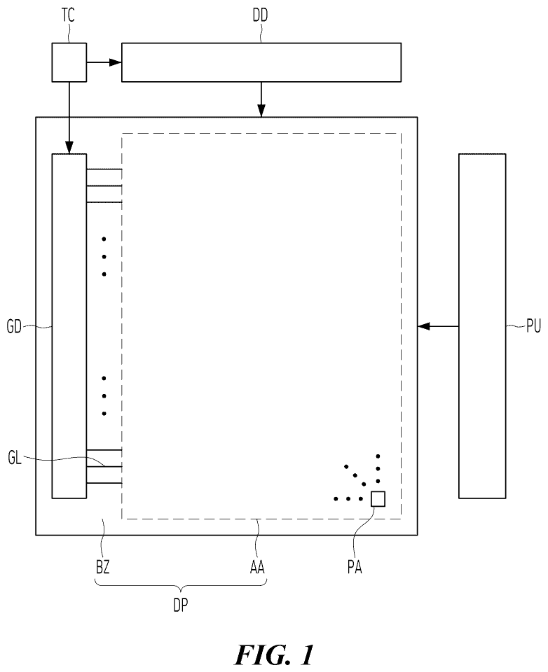

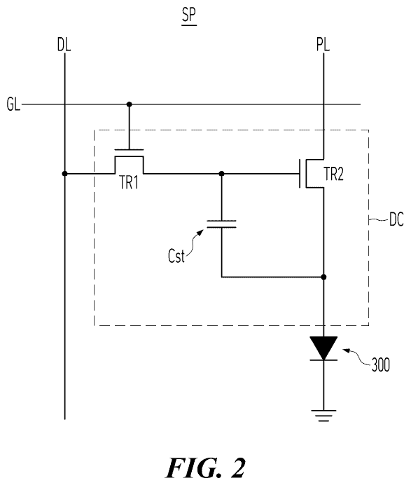

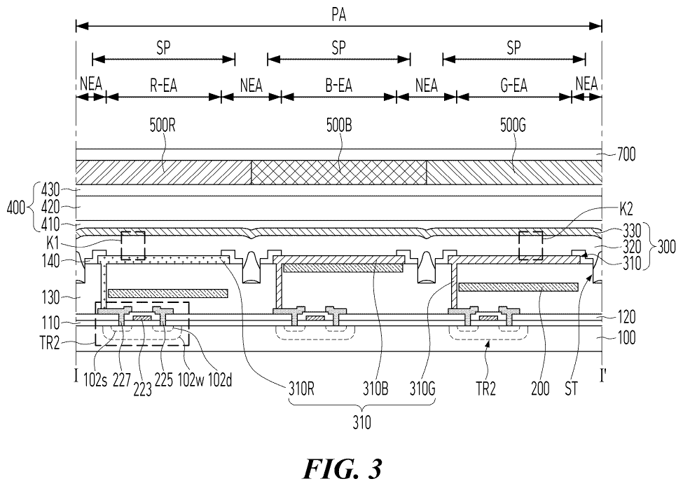

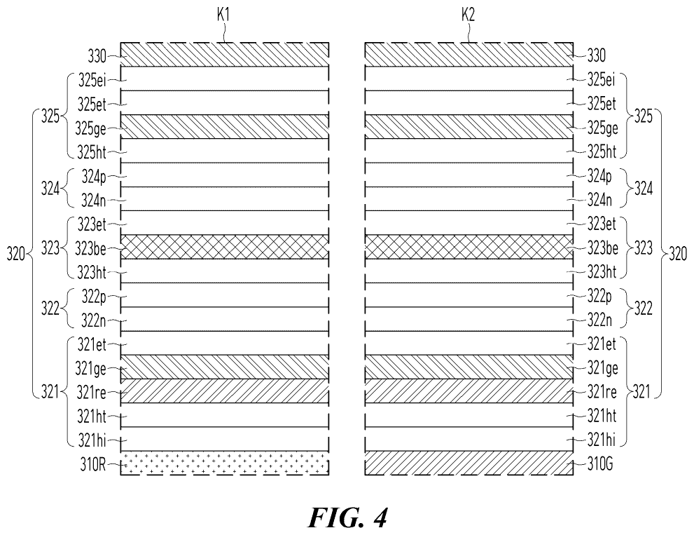

FIG. 1 is a view schematically showing a display apparatus according to an embodiment of the present disclosure. FIG. 2 is a view showing a circuit of a sub-pixel in the display apparatus according to the embodiment of the present disclosure. FIG. 3 is a view showing a cross-section of a pixel area in the display apparatus according to the embodiment of the present disclosure. FIG. 4 is an enlarged view of K1 region and K2 region in FIG. 3.

Referring to FIGS. 1 to 4, the display apparatus according to the embodiment of the present disclosure can include a display panel DP. The display panel DP can generate an image provided to a user. For example, the display panel DP can include a plurality of pixel areas PA. Each of the pixel areas PA can display various colors. For example, each pixel area PA can include a plurality of sub-pixels SP. Various signals can be provided in each sub-pixel SP through signal wirings GL, DL and PL. For example, the signal wirings GL, DL and PL can include gate lines GL applying a gate signal, data lines DL applying a data signal, and power voltage supply lines PL supplying a power voltage.

The gate lines GL can be electrically connected to a gate driver GD. The data lines DL can be electrically connected to a data driver DD. The gate driver GD and the data driver DD can be controlled by a timing controller TC. For example, the gate driver GD can receive clock signals, reset signals and a start signal from the timing controller TC, and the data driver DD can receive digital video data and a source timing signal from the timing controller TC. The power voltage supply lines PL can be electrically connected to a power unit PU.

The display panel DP can include the active area AA in which the pixel areas PA are disposed, and a bezel area BZ disposed outside the active area AA. The bezel area BZ can be disposed outside the pixel areas PA. For example, the active area AA can be surrounded by the bezel area BZ. The gate driver GD, the data driver DD, the timing controller TC and the power unit PU can be disposed outside the active area AA. For example, each of the signal wirings GL, DL and PL can include a region disposed on the bezel area BZ. At least one of the gate driver GD, the data driver DD, the timing controller TC and the power unit PU can be disposed on the bezel area BZ. For example, the display apparatus according to the embodiment of the present disclosure can be a GIP (Gate In Panel) type display apparatus in which the gate driver GD is formed on the bezel area BZ of the display panel DP.

Each of the sub-pixels SP can emit light displaying a specific color according to a signal applied though the signal wirings GL, DL and PL. For example, a driving circuit DC electrically connected to a light-emitting device 300 can be disposed in each sub-pixel SP. The display panel DP can include a device substrate 100 supporting the driving circuit DC and the light-emitting device 300 of each sub-pixel SP. For example, the driving circuit DC and the light-emitting device 300 of each sub-pixel SP can be disposed on the device substrate 100. The device substrate 100 can include various materials. For example, the device substrate 100 can be a wafer made of a semiconductor material, such as silicon. At least one of the driving circuit DC in each sub-pixel SP can be formed within the device substrate 100. Thus, in the display apparatus according to the embodiment of the present disclosure, the density of the pixel circuit DC formed in each sub-pixel SP can be improved. And, in the display apparatus according to the embodiment of the present disclosure, a process of forming the driving circuit DC of each sub-pixel SP can be simplified.

An operation of the light-emitting device 300 in each sub-pixel SP can be controlled by a signal applied through the signal wirings GL, DL and PL. For example, the driving circuit DC of each sub-pixel SP can supply a driving current corresponding to the data signal to the light-emitting device 300 of the corresponding sub-pixel SP according to the gate signal. The driving current supplied by the driving circuit DC of each sub-pixel SP can be maintained for one frame. For example, the driving circuit DC of each sub-pixel SP can include a first thin film transistor TR1, a second thin film transistor TR2 and a storage capacitor Cst.

The first thin film transistor TR1 of each sub-pixel SP can transmit the data signal to the second thin film transistor TR2 of the corresponding sub-pixel SP according to the gate signal. For example, the first thin film transistor TR1 of each sub-pixel SP can function as a switching thin film transistor. The first thin film transistor TR1 of each sub-pixel SP can include a first well region, a first drain region, a first source region, a first gate electrode, a first drain electrode and a first source electrode. For example, the first gate electrode of each sub-pixel SP can be electrically connected to the corresponding gate line GL, and the first drain electrode of each sub-pixel SP can be electrically connected to the corresponding data line DL.

The first well region, the first drain region and the first source region can be formed within the device substrate 100. For example, the first well region, the first drain region and the first source region can be formed by a process of doping the device substrate 100 with conductive impurities. The first drain region and the first source region can include different conductive impurities from the first well region. For example, the first well region can include P-type impurities, and the first drain region and the first source region can include N-type impurities. The first drain region and the first source region can be formed in the first well region. For example, a portion of the first well region disposed between the first drain region and the first source region in each sub-pixel SP can function as a first channel region of the first thin film transistor TR1 in the corresponding sub-pixel SP.

The first gate electrode can be disposed on the device substrate 100. The first gate electrode can be disposed between the first drain region and the first source region. For example, the first gate electrode can overlap the portion of the first well region, which functions as the first channel region. The first gate electrode can include a conductive material. For example, the first gate electrode can include a metal, such as aluminum (Al), chrome (Cr), copper (Cu), molybdenum (Mo), titanium (Ti) and tungsten (W). The first gate electrode can be spaced apart from the device substrate 100. The first gate electrode can be insulated from the device substrate 100. For example, the first drain region can be electrically connected to the first source region according to a voltage applied to the first gate electrode.

The first drain electrode can be disposed on the device substrate 100. The first drain electrode can include a conductive material. For example, the first drain electrode can include a metal, such as aluminum (Al), chrome (Cr), copper (Cu), molybdenum (Mo), titanium (Ti) and tungsten (W). The first drain electrode can include a different material from the first gate electrode. The first drain electrode can be disposed on a different layer from the first gate electrode. The first drain electrode can be electrically connected to the first drain region. The first drain electrode can be insulated from the first gate electrode.

The first source electrode can be disposed on the device substrate 100. The first source electrode can include a conductive material. For example, the first source electrode can include a metal, such as aluminum (Al), chrome (Cr), copper (Cu), molybdenum (Mo), titanium (Ti) and tungsten (W). The first source electrode can include a different material from the first gate electrode. The first source electrode can be disposed on a different layer from the first gate electrode. The first source electrode can be disposed on a same layer as the first drain electrode. The first source electrode can include a same material as the first drain electrode. The first source electrode can be formed by a same process as the first drain electrode. For example, the first source electrode can be formed simultaneously with the first drain electrode. The first source electrode can be electrically connected to the first source region. The first source electrode can be insulated from the first gate electrode. The first source electrode can be spaced apart from the first drain electrode.

The second thin film transistor TR2 of each sub-pixel SP can generate the driving current corresponding to the data signal. For example, the second thin film transistor TR2 of each sub-pixel SP can function as a driving thin film transistor. The second thin film transistor TR2 of each sub-pixel SP can include a second well region 102w, a second drain region 102d, a second source region 102s, a second gate electrode 223, a second drain electrode 225 and a second source electrode 227. For example, the second gate electrode 223 of each sub-pixel SP can be electrically connected to the first source electrode of the corresponding sub-pixel SP, and the second drain electrode 225 of each sub-pixel SP can be electrically connected to the corresponding power voltage supply line PL.

The second well region 102w, the second drain region 102d and the second source region 102s can be formed within the device substrate 100. For example, the second well region 102w, the second drain region 102d and the second source region 102s can be formed by a process of doping the device substrate 100 with conductive impurities. The second drain region 102d and the second source region 102s can include different conductive impurities from the second well region 102w. For example, the second well region 102w can include N-type impurities, and the second drain region 102d and the second source region 102s can include P-type impurities. The second drain region 102d and the second source region 102s can be formed in the second well region 102w. For example, a portion of the second well region 102w disposed between the second drain region 102d and the second source region 102s in each sub-pixel SP can function as a second channel region of the second thin film transistor TR2 in the corresponding sub-pixel SP.

The second well region 102w can include conductive impurities same as the first drain region and the first source region. The second well region 102w can be formed by a same process as the first drain region and the first source region. For example, the second well region 102w can be formed simultaneously with the first drain region and the first source region. The second drain region 102d and the second source region 102s can include conductive impurities same as the first well region. The second drain region 102d and the second source region 102s can be formed by a same process of the first well region. For example, the second drain region 102d and the second source region 102s can be formed simultaneously with the first well region. Thus, in the display apparatus according to the embodiment of the present disclosure, the second thin film transistor TR2 of each sub-pixel SP can be formed to have different electrical characteristics from the first thin film transistor TR1 of the corresponding sub-pixel SP, without the decrease of the process efficiency.

The second gate electrode 223 can be disposed on the device substrate 100. The second gate electrode 223 can be disposed between the second drain region 102d and the second source region 102s. For example, the second gate electrode 223 can overlap the portion of the second well region 102w which functions as the second channel region. The second gate electrode 223 can include a conductive material. For example, the second gate electrode 223 can include a metal, such as aluminum (Al), chrome (Cr), copper (Cu), molybdenum (Mo), titanium (Ti) and tungsten (W). The second gate electrode 223 can be spaced apart from the device substrate 100. The second gate electrode 223 can be insulated from the device substrate 100. For example, the portion of the second well region 102w functioning as the second channel region can have an electrical conductivity corresponding to a voltage applied to the second gate electrode 223.

The second gate electrode 223 can include a same material as the first gate electrode. The second gate electrode 223 can be disposed on a same layer as the first gate electrode. The second gate electrode 223 can be formed by a same process as the first gate electrode. For example, the second gate electrode 223 can be formed simultaneously with the first gate electrode.

The second drain electrode 225 can be disposed on the device substrate 100. The second drain electrode 225 can include a conductive material. For example, the second drain electrode 225 can include a metal, such as aluminum (Al), chrome (Cr), copper (Cu), molybdenum (Mo), titanium (Ti) and tungsten (W). The second drain electrode 225 can include a different material from the second gate electrode 223. The second drain electrode 225 can be disposed on a different layer from the second gate electrode 223. The second drain electrode 225 can be electrically connected to the second drain region 102d. The second drain electrode 225 can be insulated from the second gate electrode 223.

The second drain electrode 225 can include a same material as the first drain electrode. The second drain electrode 225 can be disposed on a same layer as the first drain electrode. The second drain electrode 225 can be formed by a same process as the first drain electrode. For example, the second drain electrode 225 can be formed simultaneously with the first drain electrode.

The second source electrode 227 can be disposed on the device substrate 100. The second source electrode 227 can include a conductive material. For example, the second source electrode 227 can include a metal, such as aluminum (Al), chrome (Cr), copper (Cu), molybdenum (Mo), titanium (Ti) and tungsten (W). The second source electrode 227 can include a different material from the second gate electrode 223. The second source electrode 227 can be disposed on a different layer from the second gate electrode 223. The second source electrode 227 can be disposed on a same layer as the second drain electrode 225. The second source electrode 227 can include a same material as the second drain electrode 225. The second source electrode 227 can be formed by a same process as the second drain electrode 225. For example, the second source electrode 227 can be formed simultaneously with the second drain electrode 225. The second source electrode 227 can be electrically connected to the second source region 102s. The second source electrode 227 can be insulated from the second gate electrode 223. The second source electrode 227 can be spaced apart from the second drain electrode 225.

The storage capacitor Cst of each sub-pixel SP can maintain a voltage applied to the second gate electrode 223 of the corresponding sub-pixel SP for one frame. For example, the storage capacitor Cst of each sub-pixel SP can be electrically connected to the second gate electrode 223 and the second source electrode 227 of the corresponding sub-pixel SP. The storage capacitor Cst of each sub-pixel SP can have a stacked structure of capacitor electrodes. For example, the storage capacitor Cst of each sub-pixel SP can include a first capacitor electrode electrically connected to the second gate electrode 223 of the corresponding sub-pixel SP and a second capacitor electrode electrically connected to the second source electrode 227 of the corresponding sub-pixel SP. The storage capacitor Cst of each sub-pixel SP can be formed by using a process of forming the first thin film transistor TR1 and the second thin film transistor TR2 in the corresponding sub-pixel SP. For example, the first capacitor electrode of each sub-pixel SP can be disposed on a same layer as the second gate electrode 223 of the corresponding sub-pixel SP, and the second capacitor electrode of each sub-pixel SP can be disposed on a same layer as the second source electrode 227 of the corresponding sub-pixel SP. Thus, in the display apparatus according to the embodiment of the present disclosure, the efficiency in a process of forming the driving circuit DC in each sub-pixel SP can be improved.

A plurality of insulating layers 110, 120, 130 and 140 for preventing unnecessary electrical connection can be disposed on the device substrate 100. For example, a gate insulating layer 110, an interlayer insulating layer 120, a planarization layer 130 and fences 140 can be disposed on the device substrate 100.

The gate insulating layer 110 can be disposed on the device substrate 100. The first gate electrode and the second gate electrode 223 of the each sub-pixel SP can be insulated from the device substrate 100 by the gate insulating layer 110. For example, an upper surface of the device substrate 100 toward the first gate electrode and the second gate electrode 223 of each sub-pixel SP can be covered by the gate insulating layer 110. The gate insulating layer 110 can be in direct contact with the upper surface of the device substrate 100. The first gate electrode and the second gate electrode 223 of each sub-pixel SP can be disposed on the gate insulating layer 110. The gate insulating layer 110 can include an insulating material. For example, the gate insulating layer 110 can include an inorganic insulating material, such as silicon oxide (SiOx) and silicon nitride (SiNx).

The interlayer insulating layer 120 can be disposed on the gate insulating layer 110. The first drain electrode and the first source electrode of each sub-pixel SP can be insulated from the first gate electrode of the corresponding sub-pixel SP. The second drain electrode 225 and the second source region 227 of each sub-pixel SP can be insulated from the second gate electrode 223 of the corresponding sub-pixel SP. For example, the first gate electrode and the second gate electrode 223 of each sub-pixel SP can be covered by the interlayer insulating layer 120. The first drain electrode, the first source electrode, the second drain electrode 225 and the second source electrode 227 of each sub-pixel SP can be disposed on the interlayer insulating layer 120. The interlayer insulating layer 120 can include an insulating material. For example, the interlayer insulating layer 120 can include an inorganic insulating material.

The planarization layer 130 can be disposed on the interlayer insulating layer 120. The planarization layer 130 can remove a thickness difference due to the driving circuit DC of each sub-pixel SP. For example, the first drain electrode, the first source electrode, the second drain electrode 225 and the second source electrode 227 of each sub-pixel SP can be covered by the planarization layer 130. An upper surface of the planarization layer 130 opposite to the device substrate 100 can be a flat surface. For example, the upper surface of the planarization layer 130 can be parallel to the upper surface of the device substrate 100. The planarization layer 130 can include an insulating material. The planarization layer 130 can include a different material from the interlayer insulating layer 120. The planarization layer 130 can include a material having a relative high fluidity. For example, the planarization layer 130 can include an organic insulating material.

The light-emitting device 300 of each sub-pixel SP can be disposed on the planarization layer 130. The light-emitting device 300 of each sub-pixel SP can emit light displaying a specific color. For example, the light-emitting device 300 of each sub-pixel SP can include a lower electrode 310, a light-emitting unit 320 and an upper electrode 330, which are sequentially stacked on the planarization layer 130 of the corresponding sub-pixel SP.

The first electrode 310 and the upper electrode 330 can include a conductive material. A transmittance of the lower electrode 310 can be larger than a transmittance of the upper electrode 330. For example, the lower electrode 310 can be a transparent electrode made of a transparent conductive material, and the upper electrode 330 can be a translucent electrode in which metals such as Ag and Mg are thinly formed. A work-function of the upper electrode 330 can be smaller than a work-function of the lower electrode 310. For example, in the display apparatus according to the embodiment of the present disclosure, the lower electrode 310 can function as anode, and the upper electrode 330 can function as cathode.

The light-emitting unit 320 can generate light having luminance corresponding to a voltage difference between the lower electrode 310 and the upper electrode 330. For example, the light-emitting unit 320 can include an emission material layer (EML). The emission material layer (EML) can generate the light using energy from the recombination of electrons and holes. For example, the emission material layer (EML) can include a host and a dopant doped into the host. Here, the term “doped” means that a first material having physical properties different from a second material that occupies most of the weight ratio in a layer is added to the layer. For example, a dopant of the emission material layer (EML) may have a weight ratio of less than 30% of the corresponding emission material layer. And, the LUMO (Lowest Unoccupied Molecular Orbital) energy level and the HOMO (High Occupied Molecular Orbital) energy level of the emission material layer (EML) can mean that the LUMO energy level and HOMO energy level of the host, that occupies most of the weight ratio in the corresponding emission material layer (EML).

The fences 140 can be disposed on the planarization layer 130. The fences 140 can insulate the lower electrode 310 of each sub-pixel SP from the lower electrode 310 of adjacent sub-pixel SP. For example, an edge of the lower electrode 310 in each sub-pixel SP can be covered by the fences 140. The fences 140 can include an insulating material. Each of the fences 140 can be a linear insulating layer with a constant thickness. For example, the fences 140 can include an inorganic insulating material.

The fences 140 can expose a portion of the lower electrode 310 in each sub-pixel SP. For example, the fences 140 can define an emission area R-EA, B-EA and G-EA in each sub-pixel SP. A region disposed between the emission areas R-EA, B-EA and G-EA can define as a non-emission area NEA. For example, the fences 140 can be disposed in the non-emission area NEA. A portion of the lower electrode 310 in the emission area R-EA, B-EA and G-EA of each sub-pixel SP can be in direct contact with the upper surface of the planarization layer 130. The light-emitting unit 320 and the upper electrode 330 of each sub-pixel SP can be stacked on a portion of the corresponding lower electrode 310 exposed by the fences 140. For example, the light-emitting unit 320 can be in direct contact with the lower electrode 310 and the upper electrode 330 in the emission area R-EA, B-EA and G-EA of each sub-pixel area SP. Thus, in the display apparatus according to the embodiment of the present disclosure, the luminance deviation due to the generating location of the light emitted from the emission area R-EA, B-EA and G-EA of each sub-pixel SP can be prevented.

The reflective electrode 200 can be disposed between the driving circuit DC and the lower electrode 310 of each sub-pixel SP. The reflective electrode 200 of each sub-pixel SP can overlap the emission area R-EA, B-EA and G-EA of the corresponding sub-pixel SP. The reflective electrode 200 of each sub-pixel SP can include a material having a high reflection. For example, the reflection electrode 200 of each sub-pixel SP can include a metal, such as aluminum (Al). Thus, in the display apparatus according to the embodiment of the present disclosure, the light generated by the light-emitting unit 320 of each sub-pixel SP can be emitted outside through the upper electrode 330 of the corresponding sub-pixel SP. And, in the display apparatus according to the embodiment of the present disclosure, the light emitted in a direction toward the lower electrode 310 of each sub-pixel SP from the light-emitting unit 320 of the corresponding sub-pixel SP can be reflected by the reflective electrode 200 of the corresponding sub-pixel SP. Therefore, in the display apparatus according to the embodiment of the preset disclosure, the light extraction efficiency of each emission area R-EA, B-EA and G-EA can be improved.

The upper electrode 330 of each sub-pixel SP can partially reflect the light. The light reflected by the upper electrode 330 of each sub-pixel SP can be re-reflected by the reflective electrode 200 of the corresponding sub-pixel SP. That is, in the display apparatus according to the embodiment of the present disclosure, a micro-cavity structure can be formed by the reflective electrode 200 and the upper electrode 330 in the emission area R-EA, B-EA and G-EA of each sub-pixel SP. Thus, in the display apparatus according to the embodiment of the present disclosure, the luminance of the light emitted from the emission area R-EA, B-EA and G-EA of each sub-pixel SP can be improved.

A voltage applied to the upper electrode 330 of each sub-pixel SP can be the same as a voltage applied to the upper electrode 330 of adjacent sub-pixel SP. For example, the upper electrode 330 of each sub-pixel SP can be electrically connected to the upper electrode 330 of adjacent sub-pixel SP. The upper electrode 330 of each sub-pixel SP can include a same material as the upper electrode 330 of adjacent sub-pixel SP. The upper electrode 330 of each sub-pixel SP can be formed by a same process as the upper electrode 330 of adjacent sub-pixel SP. For example, the upper electrode 330 of each sub-pixel SP can be formed simultaneously with the upper electrode 330 of adjacent sub-pixel SP. Thus, in the display apparatus according to the embodiment of the present disclosure, a process of forming the upper electrode 330 in each sub-pixel SP can be simplified. The upper electrode 330 of each sub-pixel SP can extend onto the fences 140. For example, the upper electrode 330 of each sub-pixel SP can be in direct contact with the upper electrode 330 of adjacent sub-pixel SP. Therefore, in the display apparatus according to the embodiment of the present disclosure, the luminance of the light emitted from the light-emitting unit 320 of each sub-pixel SP can be determined by the driving current supplied by the driving circuit DC of the corresponding sub-pixel SP.

The light generated by the light-emitting unit 320 of each sub-pixel SP can display a same color as the light generated by the light-emitting unit 320 of adjacent sub-pixel SP. For example, the light generated by the light-emitting unit 320 of each sub-pixel SP can display white color. The light-emitting unit 320 of each sub-pixel SP can include a plurality of emission stacks 321, 323 and 325. Each of the emission stacks 321, 323 and 325 can generate light. For example, in the display apparatus according to the embodiment of the present disclosure, the light-emitting unit 320 of each sub-pixel SP can include a first emission stack 321, a first charge generation layer 322, a second emission stack 323, a second charge generation layer 324 and a third emission stack 325, which are sequentially stacked. The light generated by the second emission stack 323 can display a color complementary to the color realized by the light generated by the first emission stack 321 and/or the color realized by the light generated by the third emission stack 323.

Each of the charge generation layers 322 and 324 can supply electrons or holes to adjacent emission stack 321, 323 and 325. For example, the first charge generation layer 322 can have a stacked structure of first n-type charge generating layer 322n and a first p-type charge generating layer 322p, and the second charge generation layer 324 can have a stacked structure of a second n-type charge generating layer 324n and a second p-type charge generating layer 324p. the n-type charge generating layer 322n and 324n of each charge generation layer 322 and 324 can be disposed closer to the lower electrode 310 than the p-type charge generating layer 322p of the corresponding charge generation layer 322 and 324. For example, the first emission stack 321 can be disposed between the lower electrode 310 and the first n-type charge generating layer 322n, the second emission stack 323 can be disposed between the first p-type charge generating layer 322p and the second n-type charge generating layer 324n, and the third emission stack 325 can be disposed between the second p-type charge generating layer 324p and the upper electrode 330.

Each of the first emission stack 321, the second emission stack 323 and the third emission stack 325 can further include at least one functional layer to smoothly supply holes or electrons. For example, the function layer can be one of a hole injection layer (HIL), a hole transport layer (HTL), an electron transport layer (ETL) and an electron injection layer (EIL). The first emission stack 321, the second emission stack 323 and the third emission stack 325 can have different stacked structures. For example, in the display apparatus according to the embodiment of the present disclosure, the first emission stack 321 can include a hole injection layer 321hi, a first hole transport layer 321ht, a red emission material layer 321re, a first green emission material layer 321ge and a first electron transport layer 321et, which are sequentially stacked, the second emission stack 323 can include a second hole transport layer 323ht, a blue emission material layer 323be and a second electron transport layer 323et, which are sequentially stacked, and the third emission stack 325 can include a third hole transport layer 325ht, a second green emission material layer 325ge, a third electron transport layer 325et and an electron injection layer 325ei, which are sequentially stacked. The red emission material layer 321re and the first green emission material layer 321ge of the first emission stack 321 can generate the light using holes supplied through the hole injection layer 321hi and the first hole transport layer 321ht from the lower electrode 310 and electrons supplied through the first electron transport layer 321et from the first n-type charge generating layer 322n. The blue emission material layer 323be of the second emission stack 323 can generate the light using holes supplied through the second hole transport layer 323ht from the first p-type charge generating layer 322p and electrons supplied through the second electron transport layer 323et from the second n-type charge generating layer 324n. The second green emission material layer 325ge of the third emission stack 325 can generate the light using holes supplied through the third hole transport layer 325ht from the second p-type charge generating layer 324p and electrons supplied through the third electron transport layer 325et and the electron injection layer 325ei from the upper electrode 330. Thus, in the display apparatus according to the embodiment of the present disclosure, electrons and holes may be supplied to the first emission stack 321, the second emission stack 323 and the third light emission stack 325 in a balanced manner.

A dopant of the second green emission material layer 325ge can be the same as a dopant of the first green emission material layer 321ge. For example, the light generated by the second green emission material layer 325ge can have a same wavelength range as the light generated by the first green emission material layer 321ge. Thus, in the display apparatus according to the embodiment of the present disclosure, the luminance and reproduction of the green color recognized by the user can be improved.

The light emitted from the emission area R-EA, B-EA and G-EA of each sub-pixel SP can display a different color from the emission area R-EA, B-EA and G-EA of adjacent sub-pixel SP. For example, the emission area R-EA, B-EA and G-EA of each sub-pixel SP can be one of a red emission area R-EA emitting red light, a blue emission area B-EA emitting blue light and green emission area G-EA emitting green light. The light-emitting unit 320 of each sub-pixel SP can have a stacked structure same as the light-emitting unit 320 of adjacent sub-pixel SP. The light-emitting unit 320 of each sub-pixel SP can be formed by a same process as the light-emitting unit 320 of adjacent sub-pixel SP. For example, the light-emitting unit 320 of each sub-pixel SP can be formed simultaneously with the light-emitting unit 320 of adjacent sub-pixel SP. Thus, in the display apparatus according to the embodiment of the present disclosure, a process of forming the light-emitting unit 320 of each sub-pixel SP can be simplified. The light-emitting unit 320 of each sub-pixel SP can include a region being in direct contact with the light-emitting unit 320 of adjacent sub-pixel SP.

A distance between the reflective electrode 200 and the lower electrode 310 in the emission area R-EA, B-EA and G-EA of each sub-pixel SP can be changed according to the color realized by the emission area R-EA, B-EA and G-EA of the corresponding sub-pixel SP. For example, a distance between the reflective electrode 200 and the lower electrode 310 in the red emission area R-EA of each sub-pixel SP can be larger than a distance between the reflective electrode 200 and the lower electrode 310 in the green emission area G-EA of each sub-pixel SP. A distance between the reflective electrode 200 and the lower electrode 310 in the green emission area G-EA of each sub-pixel SP can be larger than a distance between the reflective electrode 200 and the lower electrode 310 in the blue emission area B-EA of each sub-pixel SP. For example, the reflective electrode 200 can be in direct contact with the lower electrode 310 in the blue emission area B-EA of each sub-pixel SP. Thus, in the display apparatus according to the embodiment of the present disclosure, a wavelength of the light emitted from each emission area R-EA, B-EA and G-EA can be determined by the micro-cavity structure of the corresponding emission area R-EA, B-EA and G-EA. For example, in the display apparatus according to the embodiment of the present disclosure, the red light among the light generated by the light-emitting unit 320 of the red emission area R-EA in each sub-pixel SP can be amplified by a distance between the reflective electrode 200 and the lower electrode 310 of the red emission area R-EA in the corresponding sub-pixel SP, the blue light among the light generated by the light-emitting unit 320 of the blue emission area B-EA in each sub-pixel SP can be amplified by a distance between the reflective electrode 200 and the lower electrode 310 of the blue emission area B-EA in the corresponding sub-pixel SP, and the green light among the light generated by the light-emitting unit 320 of the green emission area G-EA in each sub-pixel SP can be amplified by a distance between the reflective electrode 200 and the lower electrode 310 of the green emission area G-EA in the corresponding sub-pixel SP. That is, in the display apparatus according to the embodiment of the present disclosure, the light emitted from each emission area R-EA, B-EA and G-EA can display a different color from the light emitted from adjacent emission area R-EA, B-EA and G-EA by the micro-cavity structure. Therefore, in the display apparatus according to the embodiment of the present disclosure, the reproduction of the light emitted from the emission area R-EA, B-EA and G-EA of each sub-pixel SP can be improved.

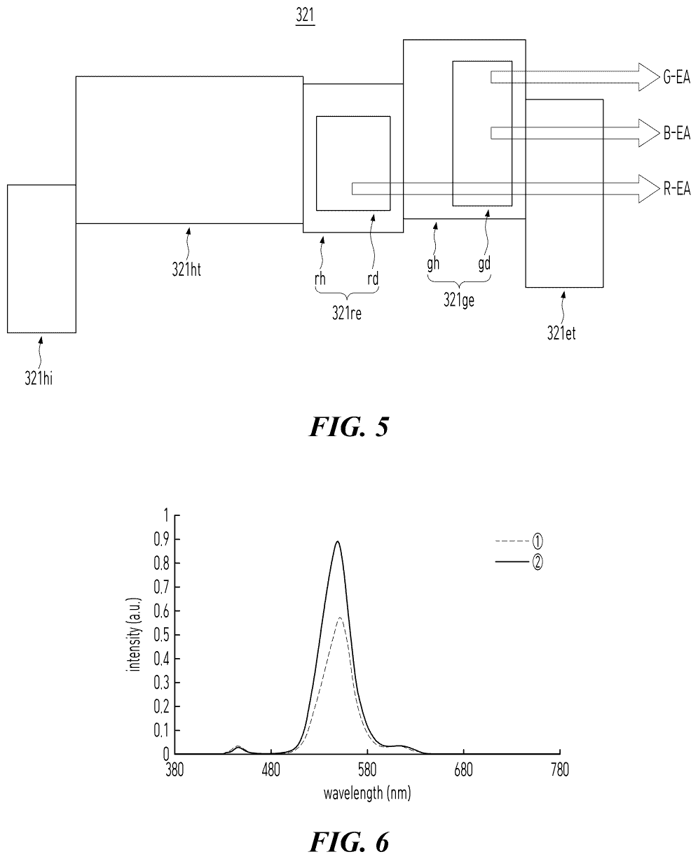

At least one of the lower electrodes 310 in each pixel area PA can have different characteristics from the remaining lower electrodes 310 in the corresponding pixel area PA. For example, the lower electrodes 310 of each pixel area PA can include a red lower electrode 310R on the red emission area R-EA, a blue lower electrode 310B on the blue emission area B-EA and a green lower electrode 310G on the green emission area G-EA, the red lower electrode 310R can have a work-function smaller than the blue lower electrode 310B and the green lower electrode 310G. The red lower electrode 310R can include a different material from the blue lower electrode 310B and the green lower electrode 310G. For example, the red lower electrode 310R can include one of the barium oxide (BaO), aluminum (Al), molybdenum trioxide (MoO₃), silver (Ag), titanium (Ti), chromium (Cr), tungsten (W) and molybdenum (Mo) which have a relative small work-function. Thus, in the display apparatus according to the embodiment of the present disclosure, the supply of holes through the hole injection layer 321hi and the first hole transport layer 321ht of the first emission stack 321 from the red lower electrode 310R can be delayed than the supply of holes through the hole injection layer 321hi and the first hole transport layer 321ht of the first emission stack 321 from the blue lower electrode 310B and the supply of holes through the hole injection layer 321hi and the first hole transport layer 321ht of the first emission stack 321 from the green lower electrode 310G. That is, in the display apparatus according to the embodiment of the present disclosure, the location at which electrons and holes are recombined in the first emission stack 321 of the red emission area R-EA can be disposed closer to the first hole transport layer 321ht than the location at which electrons and holes are recombined in the first emission stack 321 of the blue emission area B-EA and the location at which electrons and holes are recombined in the first emission stack 321 of the green emission area G-EA. For example, electrons and holes supplied to the first emission area 321 of the red emission area R-EA can be recombined in the red emission material layer 321re, and a red dopant rd of the red emission material layer 321re can generate the light using the energy by the recombination of electrons and holes, as shown in FIG. 5. Electrons and holes supplied to the first emission area 321 of the blue emission area B-EA and the first emission area 321 of the green emission area G-EA can be recombined in the first green emission material layer 321ge, and a green dopant gd of the first green emission material layer 321ge can generate the light using the energy by the recombination of electrons and holes. Therefore, in the display apparatus according to the embodiment of the present disclosure, the first emission stack 321 of the red emission area R-EA can generate red light, and the first emission stack 321 of the blue emission area B-EA and the green emission area G-EA can generate green light.

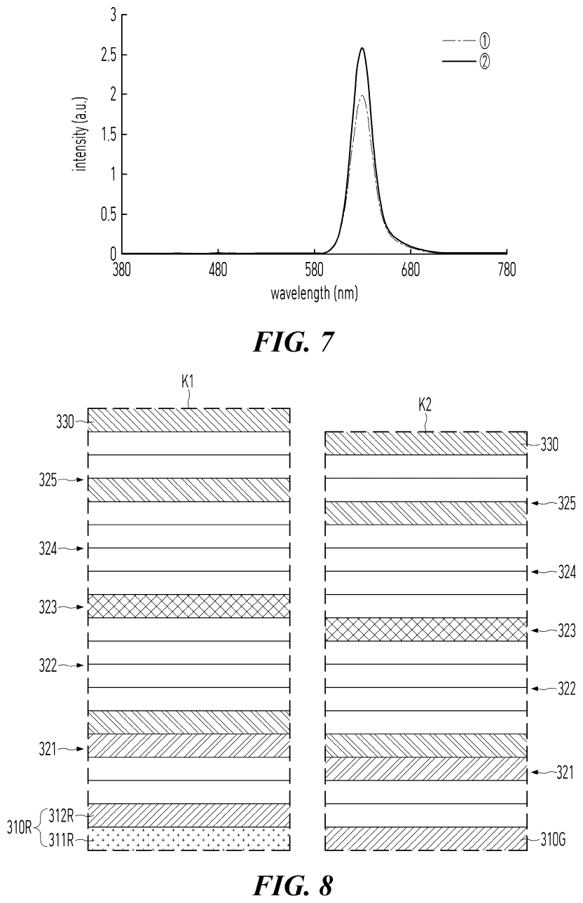

FIG. 6 is a graph showing the intensity of green color in a comparison display apparatus \textcircled{1} in which the lower electrode 310 of each emission area R-EA, B-EA and G-EA includes a same material and the display apparatus \textcircled{2} according to the embodiment of the present disclosure. FIG. 7 is a graph showing the intensity of red color in the comparison display apparatus \textcircled{1} and the display apparatus \textcircled{2} according to the embodiment of the present disclosure.

Referring to FIGS. 6 and 7, in the display apparatus \textcircled{2} according to the embodiment of the present disclosure, the green color and the red color recognized by the user can have a relatively high intensity. That is, in the display apparatus \textcircled{2} according to the embodiment of the present disclosure, red light can be generated by the first emission stack 321 of the red emission area R-EA and green light can be generated by the first emission stack 321 of the blue emission area B-EA and the green emission area G-EA, such that the efficiency of the red emission area R-EA and the efficiency of the green emission area G-EA can be improved. Thus, in the display apparatus according to the embodiment of the present disclosure, the overall luminance can be increased. And, in the display apparatus according to the embodiment of the present disclosure, the low-power driving can be possible, and the power consumption can be reduced.

As shown in FIGS. 3 and 4, in the display apparatus according to the embodiment of the present disclosure, a separation trench ST can be disposed within the non-emission area NEA. The separation trench ST can be disposed outside the fences 140. For example, the separation trench ST can be disposed between adjacent fences 140. The separation trench ST can extend in a direction toward the device substrate 100. For example, a portion of the separation trench ST can be surrounded by the planarization layer 130. The separation trench ST can be a groove shape in which a portion of the planarization layer 130 is removed. For example, the upper surface of the planarization layer 130 disposed between the emission areas R-EA, B-EA and G-EA can be separated by the separation trench ST. The first charge generation layer 322 and the second chare generation layer 324 of each sub-pixel SP can be separated from the first charge generation layer 322 and the second charge generation layer 324 of adjacent sub-pixel SP by the separation trench ST. For example, an upper end of the separation trench ST can be covered by the third emission stack 325 of each sub-pixel SP. An air-gap can be formed within the separation trench ST. Thus, in the display apparatus according to the embodiment of the present disclosure, the leakage current due to the charge generation layers 322 and 324 can be prevented. That is, in the display apparatus according to the embodiment of the present disclosure, the malfunction of the light-emitting device 300 in each sub-pixel SP can be prevented. Therefore, in the display apparatus according to the embodiment of the present disclosure, the quality of the image can be improved. And, in the display apparatus according to the embodiment of the present disclosure, the density of the light-emitting devices 300 can be improved.

An encapsulation structure 400 can be disposed on the light-emitting device 300 of each sub-pixel SP. The encapsulation structure 400 can prevent damage of the light-emitting devices 300 due to external moisture and impact. The encapsulation structure 400 can have a multi-layer structure. For example, the encapsulation structure 400 can include a first encapsulating layer 410, a second encapsulating layer 420 and a third encapsulating layer 430, which are sequentially stacked. The first encapsulating layer 410, the second encapsulating layer 420 and the third encapsulating layer 430 can include an insulating material. The second encapsulating layer 420 can include a different material from the first encapsulating layer 410 and the third encapsulating layer 430. For example, the first encapsulating layer 410 and the third encapsulating layer 430 can be an inorganic encapsulating layer including an inorganic insulating material, and the second encapsulating layer 420 can be an organic encapsulating layer including an organic insulating material. Thus, in the display apparatus according to the embodiment of the present disclosure, the damage of the light-emitting devices 300 due to the external moisture and impact can be effectively prevented. A thickness difference due to the light-emitting device 300 of each sub-pixel SP can be removed by the second encapsulating layer 420. For example, an upper surface of the encapsulation structure 400 opposite to the device substrate 100 can be flat. The second encapsulating layer 420 can have a greater thickness than the first encapsulating layer 410 and the third encapsulating layer 430.

Color filters 500R, 500B and 500G can be disposed on the encapsulation structure 400. The color filters 500R, 500B and 500G can overlap the emission areas R-EA, B-EA and G-EA of each pixel area PA. For example, the color filters 500R, 500B and 500G can include a red color filter 500R overlapping with the red emission area R-EA, a blue color filter 500B overlapping with the blue emission area B-EA and a green color filter 500G overlapping with the green emission area G-EA. Each of the color filter 500R, 500B and 500G of each emission area R-EA, B-EA and G-EA can have a larger size than the corresponding emission area R-EA, B-EA and G-EA. For example, a boundary between adjacent color filters 500R, 500B and 500G can overlap the separation trench ST. Thus, in the display apparatus according to the embodiment of the present disclosure, the light emitted from the light-emitting device 300 of each sub-pixel PA must pass through the color filters 500R, 500B and 500G of the corresponding sub-pixel SP. Therefore, in the display apparatus according to the embodiment of the present disclosure, the color reproduction can be improved.

The filter passivation layer 700 can be disposed on the color filters 500R, 500B and 500G. The filter passivation layer 700 can prevent the damage of the color filters 500R, 500B and 500G due to the external impact and moisture. The filter passivation layer 700 can include an insulating material. For example, the filter passivation layer 700 can include an inorganic insulating material and an organic insulating material. The filter passivation layer 700 can have a multi-layer structure. For example, the filter passivation layer 700 can have a structure in which an inorganic insulating layer made of an inorganic insulating material is disposed on an organic insulating layer made of an organic insulating material. Thus, in the display apparatus according to the embodiment of the present disclosure, the damage of the color filters 500R, 500B and 500G due to the external impact and moisture can be effectively prevented.

Accordingly, the display apparatus according to the embodiment of the present disclosure can include the light-emitting devices 300 on the emission area R-EA, B-EA and G-EA of each sub-pixel SP, wherein each of the light-emitting device 300 can include the lower electrode 310, the light-emitting unit 320 and the upper electrode 330, which are sequentially stacked, wherein the first emission stack 321 of the light-emitting unit 320 can have a stacked structure of the red emission material layer 321re and the first green emission material layer 321ge, and wherein the red lower electrode 310R on the red emission area R-EA can have a smaller work-function from the blue lower electrode 310B on the blue emission area B-EA and the green lower electrode 310G on the green emission area G-EA. That is, in the display apparatus according to the embodiment of the present disclosure, the supply of holes through the hole injection layer 321hi and the first hole transport layer 321ht of the first emission stack 321 from the red lower electrode 310R in the red emission area R-EA can be relatively delayed. Thus, in the display apparatus according to the embodiment of the present disclosure, the first emission stack 321 of the red emission area R-EA can generate the red light, and the first emission stack 321 of the blue emission area B-EA and the first emission stack 321 of the green emission area G-EA can generate the green light. Therefore, in the display apparatus according to the embodiment of the present disclosure, the efficiency of the red emission area R-EA and the efficiency of the green emission area G-EA can be improved. And, in the display apparatus according to the embodiment of the present disclosure, the overall luminance can be increased.

The display apparatus according to the embodiment of the present disclosure is described that the driving circuit DC of each sub-pixel SP consists of the first thin film transistor TR1, the second thin film transistor TR2 and the storage capacitor Cst. However, in the display apparatus according to another embodiment of the present disclosure, the driving circuit DC of each sub-pixel SP can include a driving thin film transistor and at least one switching thin film transistor. For example, in the display apparatus according to another embodiment of the present disclosure, the driving circuit DC of each sub-pixel SP can further include a third thin film transistor for initializing the storage capacitor Cst of the corresponding sub-pixel SP according to the gate signal. The third thin film transistor of each sub-pixel SP can include a third well region, a third drain region, a third source region, a third gate electrode, a third drain electrode and a third source electrode. The third well region, the third drain region and the third source region can be formed within the device substrate 100. The third gate electrode of each sub-pixel SP can be electrically connected to the corresponding gate line GL, the third drain electrode of each sub-pixel SP can be electrically connected to an initial line applying an initial signal, and the third source electrode of each sub-pixel SP can be electrically connected to the storage capacitor Cst of the corresponding sub-pixel SP. Thus, in the display apparatus according to another embodiment of the present disclosure, the degree of freedom in configuration of each driving circuit DC can be improved.

In the display apparatus according to the embodiment of the present disclosure, the location and the electric connection of the first drain electrode, the first source electrode, the second drain electrodes 225 and the second source electrode 227 in each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain electrode of the corresponding driving circuit DC. Thus, in the display apparatus according to another embodiment of the present disclosure, the degree of freedom in the configuration of each driving circuit DC and the type of each thin film transistor TR1 and TR2 can be improved.

The display apparatus according to the embodiment of the present disclosure is described that the first well, the second drain region 102d and the second source region 102s of each sub-pixel SP can include P-type impurities, and the first drain region, the first source region and the second well region 102w of each sub-pixel SP can include N-type impurities. However, in the display apparatus according to another embodiment of the present disclosure, the second well region 102w of each sub-pixel SP can include conductive impurities same as the first well region of the corresponding sub-pixel SP. For example, in the display apparatus according to another embodiment of the present disclosure, the first well region and the second well region 102w of each sub-pixel SP can include P-type impurities. The first drain region, the first source region, the second drain region 102d and the second source region 102s of each sub-pixel SP can include N-type impurities. Thus, in the display apparatus according to another embodiment of the present disclosure, the degree of freedom in the configuration of each driving circuit DC and the type of each thin film transistor TR1 and TR2 can be improved.

The display apparatus according to the embodiment of the present disclosure is described that the device substrate 100 can be a wafer formed of a semiconductor material, such as silicon. However, in the display apparatus according to another embodiment of the present disclosure, the device substrate 100 can include glass or plastic. In the display apparatus according to another embodiment of the present disclosure, the driving circuit DC of each sub-pixel SP can be formed on the upper surface of the device substrate 100. For example, in the display apparatus according to another embodiment of the present disclosure, a buffer layer including an inorganic insulating layer, such as silicon oxide (SiOx) and silicon nitride (SiNx), can be formed on the upper surface of the device substrate 100, and the first thin film transistor TR1 and the second thin film transistor TR2 of each sub-pixel SP can include a semiconductor pattern formed on the buffer layer. The semiconductor pattern can include a semiconductor material. For example, a first semiconductor pattern of the first thin film transistor TR1 and a second semiconductor pattern of the second thin film transistor TR2 in each sub-pixel SP can include an oxide semiconductor, such as IGZO. Thus, in the display apparatus according to another embodiment of the present disclosure, the degree of freedom in the material of the device substrate 100 and the configuration of each driving circuit DC can be improved.

The display apparatus according to the embodiment of the present disclosure is described that the red emission material layer 321re and the first green emission material layer 321ge can include an electron transporting host and a hole transporting host. For example, a host gh of the first green emission material layer 321ge can include a same material as a host rh of the red emission material layer 321re. Thus, in the display apparatus according to another embodiment of the present disclosure, electrons and holes can move smoothly between the red emission material layer 321re and the first green emission material layer 321ge. And, in the display apparatus according to another embodiment of the present disclosure, a process of forming the first emission stack 321 on each emission area R-EA, B-EA and G-EA can be simplified. Therefore, in the display apparatus according to the embodiment of the present disclosure, the efficiency of the red emission area R-EA and the efficiency of the green emission area G-EA can be effectively improved.

In the display apparatus according to another embodiment of the present disclosure, the host gh of the first green emission material layer 321ge can include a different material from the host rh of the red emission material layer 321re. For example, the first green emission material layer 321ge can include a single hole transporting host. Thus, in the display apparatus according to the embodiment of the present disclosure, the flow of electrons supplied to the red emission material layer 321re through the first green emission material layer 321ge in the emission area R-EA, B-EA and G-EA of each sub-pixel SP can be slowed down. That is, in the display apparatus according to another embodiment of the present disclosure, the location in which electrons and holes supplied to the first emission stack 321 are recombined can be adjusted by using the host gh of the first green emission material layer 321ge. For example, in the display apparatus according to another embodiment of the present disclosure, electrons and holes supplied to the first emission stack 321 of the red emission area R-EA can be recombined at the central area of the red emission material layer 321re by the host gh of the first green emission material layer 321ge, and electrons and holes supplied to the first emission stack 321 of the green emission area G-EA can be recombined at the central area of the first green emission material layer 321ge. Therefore, in the display apparatus according to another embodiment of the present disclosure, the color reproduction of the red color by the red emission area R-EA and the color reproduction of the green color by the green emission area G-EA can be improved.

The display apparatus according to the embodiment of the present disclosure is described that the red lower electrode 310R can have a work-function smaller from the blue lower electrode 310B and the green lower electrode 310G. However, in the display device according to another embodiment of the present disclosure, the supply of holes through the hole injection layer 321hi and the first hole transport layer 321ht of the first emission stack 321 from the red lower electrode 310R in the red emission area R-EA can be delayed in various ways. For example, in the display device according to another embodiment of the present disclosure, the red lower electrode 310R can have a resistance larger than the blue lower electrode 310B and the green lower electrode 310G. For example, the red lower electrode 310R can include one of nickel oxide (NiO₃), manganese oxide (MnO₃), iron oxide (FeO₃), and vanadium dioxide (VO₂). The red lower electrode 310R can have an electrical conductivity smaller than the blue lower electrode 310B and the green lower electrode 310G. For example, the red lower electrode 310R can include a doped oxide. Here, the doped oxide can be one of titanium dioxide (TiO₂), zinc oxide (ZnO), tin oxide (SnO), and cerium oxide (CeO) doped with one of sulfur(S), bromine (Br), chlorine (Cl), and nitrogen (N). The red lower electrode 310R can include a conductive polymer. Thus, in the display apparatus according to another embodiment of the present disclosure, the degree of freedom for the material of the red lower electrode 310R can be improved.

The red lower electrode 310R can be disposed on a same layer as the blue lower electrode 310B and the green lower electrode 310G. The red lower electrode 310R can have a same thickness as the blue lower electrode 310B and the green lower electrode 310G. For example, in the display apparatus according to the embodiment of the present disclosure, the red lower electrode 310R can have a stacked structure same as the blue lower electrode 310B and the green lower electrode 310G. However, in the display apparatus according to another embodiment of the present disclosure, the red lower electrode 310R can have a stacked structure different from the blue lower electrode 310B and the green lower electrode 310G. For example, in the display apparatus according to another embodiment of the present disclosure, the red lower electrode 310R can have a stacked structure of a first electrode layer 311R and a second electrode layer 312R, and the green lower electrode 310G can have a single layer structure, as shown in FIG. 8.

The first electrode layer 311R can include a same material as the green lower electrode 310G. The first electrode layer 311R can be disposed on a same layer as the green lower electrode 310G. The first electrode layer 311R can be formed by a same process as the green lower electrode 310G. For example, the first electrode layer 311R can be formed simultaneously with the green lower electrode 310G. The first electrode layer 311R can have a same thickness as the green lower electrode 310G.

The second electrode layer 312R can be disposed on the first electrode layer 311R. The second electrode layer 312R can include a different material from the first electrode layer 311R. A thickness of the second electrode layer 312R can be different from a thickness of the first electrode layer 311R. For example, the second electrode layer 312R can have a smaller work-function than the first electrode layer 311R. An electrical conductivity of the second electrode layer 312R can be smaller than an electrical conductivity of the first electrode layer 311R. The second electrode layer 312R can have a larger resistance than the first electrode layer 311R. The second electrode layer 312R can be disposed between the first electrode layer 311R and the first emission stack 321. Thus, in the display apparatus according to another embodiment of the present disclosure, holes supplied to the first emission stack 321 from the red lower electrode 310R can be delayed by the second electrode layer 312R. Therefore, in the display apparatus according to another embodiment of the present disclosure, the degree of freedom for the stacked structure of the red lower electrode 310R can be improved.

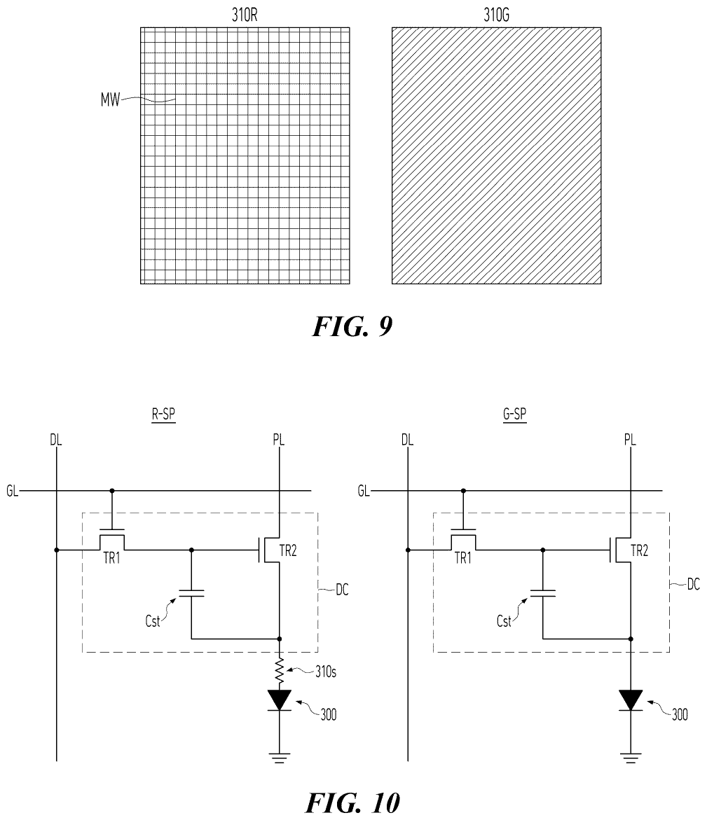

In the display device according to another embodiment of the present disclosure, the red lower electrode 310R can have a planar shape different from the blue lower electrode 310B and the green lower electrode 310G. For example, in the display apparatus according to another embodiment of the present disclosure, a plane of the red lower electrode 310R can have a mesh shape in which the fine wirings MW cross each other, and a plane of the green lower electrode 310G can have a flat plate shape, as shown in FIG. 9. Thus, in the display apparatus according to another embodiment of the present disclosure, the plane of the red lower electrode 310R can have a smaller area than the plane of the green lower electrode 310G. That is, in the display apparatus according to another embodiment of the present disclosure, a resistance of the red lower electrode 310R can be larger than a resistance of the green lower electrode 310G by the planar shape of the red lower electrode 310R. For example, in the display apparatus according to another embodiment of the present disclosure, the red lower electrode 310R can be formed of a same material as the green lower electrode 310G. Therefore, in the display apparatus according to another embodiment of the present disclosure, the degree of freedom for the material and the shape of the red lower electrode 310R can be improved.

In the display device according to another embodiment of the present disclosure, the red lower electrode 310R can be formed simultaneously with the blue lower electrode 310B and the green lower electrode 310G. For example, in the display apparatus according to another embodiment of the present disclosure, a resistance region 310s can be disposed between the driving circuit DC and the light-emitting device 300 of a red sub-pixel SP including the red emission area, as shown in FIG. 10. The resistance region 310s can increase a resistance between the driving circuit DC and the light-emitting device 300 of the red sub-pixel R-SP. For example, the resistance region 310s can be formed by increasing a length of a wiring electrically connecting between the driving circuit DC and the light-emitting device 300 of the red sub-pixel R-SP. Thus, in the display apparatus according to another embodiment of the present disclosure, a resistance between the driving circuit DC and the light-emitting device 300 in the red sub-pixel R-SP can be larger than a resistance between the driving circuit DC and the light-emitting device 300 in a green sub-pixel G-SP including the green emission area. For example, in the display apparatus according to another embodiment of the present disclosure, a lower electrode of the red sub-pixel R-SP can have a longer length than a lower electrode of the green sub-pixel G-SP. Therefore, in the display apparatus according to another embodiment of the present disclosure, the efficiency of the red sub-pixel R-SP and the efficiency of the green sub-pixel G-SP can be effectively improved, without the decrease of the process efficiency. And, in the display apparatus according to another embodiment of the present disclosure, the production energy can be reduced by the process optimization.

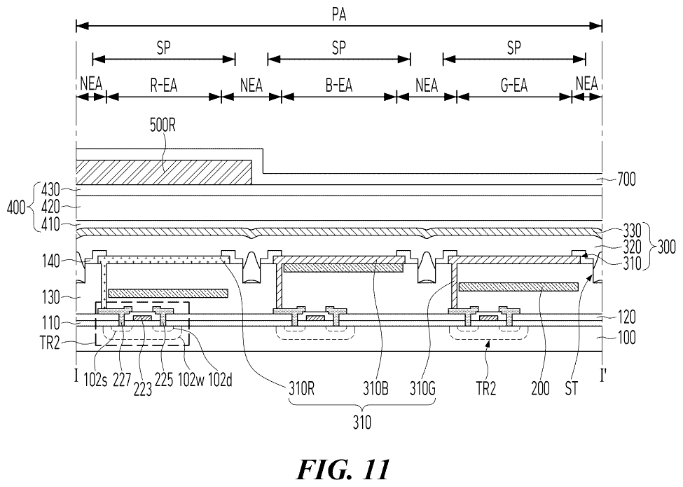

The display apparatus according to the embodiment of the present disclosure is described that the red color filter 500R can be disposed on the red emission area R-EA, the blue color filter 500B can be disposed on the blue emission area B-EA, and the green color filter 500G can be disposed on the green emission area G-EA. However, in the display device according to another embodiment of the present disclosure, some of the color filters 500R, 500B and 500G can be omitted. For example, in the display apparatus according to another embodiment of the present disclosure, only the red color filter 500R can be disposed between the encapsulation structure 400 and the filter passivation layer 700, as shown in FIG. 11. The filter passivation layer 700 disposed on the blue emission area B-EA and the green emission area G-EA can be in direct contact with the third encapsulating layer 430. Thus, in the display apparatus according to another embodiment of the present disclosure, the efficiency and the color reproduction of the red light generated by the first emission stack of the red emission area R-EA can be improved.

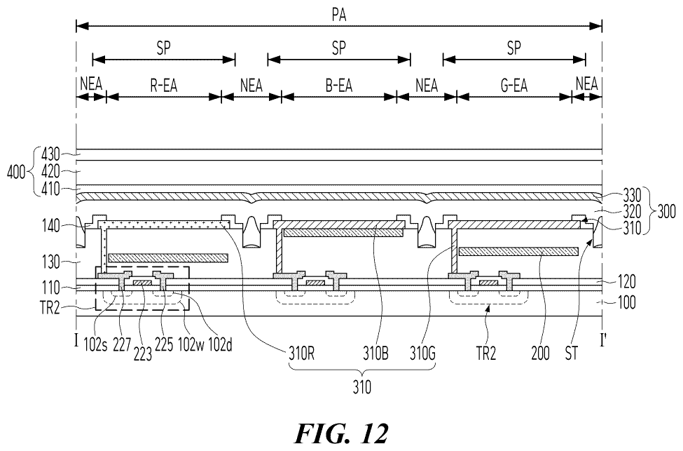

In the display apparatus according to another embodiment of the present disclosure, all of the color filters 500R, 500B and 500G can be omitted. For example, the third encapsulating layer 430 can be exposed to the outside, as shown in FIG. 12. Thus, in the display apparatus according to another embodiment of the present disclosure, the process efficiency can be greatly increased. Therefore, in the display apparatus according to another embodiment of the present disclosure, the production energy can be reduced by the process optimization.

In the result, the display apparatus according to the embodiments of the present disclosure can comprise the first light-emitting device disposed on the first emission area and the second light-emitting device disposed on the second emission area, wherein each of the first light-emitting device and the second light-emitting device can have a stacked structure of the lower electrode, the light-emitting unit and the upper electrode, wherein the light-emitting unit can include the emission stack having a stacked structure of the red emission material layer and the green emission material layer, wherein the upper electrode can have a work-function smaller than the lower electrode, wherein the lower electrode disposed on the second emission area can have a work-function and/or a resistance different from the lower electrode disposed on the first emission area. Thus, in the display apparatus according to the embodiments of the present disclosure, the efficiency of the first light-emitting device and the efficiency of the second light-emitting device can be improved. Thereby, in the display apparatus according to the embodiments of the present disclosure, the overall luminance can be improved. And, in the display apparatus according to the embodiments of the present disclosure, the low-power driving can be possible, and the power consumption can be reduced.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a first lower electrode on a first emission area of a device substrate;
a second lower electrode on a second emission area of the device substrate, the second lower electrode spaced apart from the first lower electrode;
a light-emitting unit on the first lower electrode and the second lower electrode, the light-emitting unit including a plurality of emission stacks; and
an upper electrode on the light-emitting unit, the upper electrode overlapping with the first emission area and the second emission area,
wherein the upper electrode has a work-function lower than the first lower electrode and the second lower electrode,
wherein the plurality of emission stacks include a first emission stack having a stacked structure of a red emission material layer and a first green emission material layer, and
wherein a work-function of the second lower electrode is different from a work-function of the first lower electrode.

2. The display apparatus according to claim 1, wherein the second lower electrode is on a different layer from the first lower electrode.

3. The display apparatus according to claim 1, wherein the second lower electrode includes a different material from the first lower electrode.

4. The display apparatus according to claim 3, wherein a resistance of the second lower electrode is larger than a resistance of the first lower electrode.

5. The display apparatus according to claim 1, wherein the first emission stack is disposed close to the first lower electrode and the second lower electrode.

6. The display apparatus according to claim 5, wherein the red emission material layer is between the first lower electrode and the first green emission material layer and between the second lower electrode and the first green emission material layer.

7. The display apparatus according to claim 5, wherein the plurality of emission stacks include a second emission stack and a third emission stack,
wherein the second emission stack between the first emission stack and the third emission stack includes a blue emission material layer, and
wherein the third emission stack between the second emission stack and the upper electrode includes a second green emission material layer.

8. The display apparatus according to claim 7, wherein the second green emission material layer includes a same dopant as the first green emission material.

9. The display apparatus according to claim 7, wherein a host of the second green emission material layer includes a different material from a host of the first green emission material layer.

10. The display apparatus according to claim 1, wherein the first green emission material layer includes a single hole transporting host.

11. A display apparatus comprising:
a first light-emitting device including a first lower electrode, a first light-emitting unit and a first upper electrode, which are stacked on a first emission area of a device substrate;
a second light-emitting device including a second lower electrode, a second light-emitting unit and a second upper electrode, which are stacked on a second emission area of the device substrate; and
an encapsulation structure covering the first light-emitting device and the second light-emitting device,
wherein each of the first light-emitting unit and the second light-emitting unit includes an emission stack having a stacked structure of a red emission material layer and a green emission material layer,
wherein the second upper electrode of the second light-emitting device is electrically connected to the first upper electrode of the first light-emitting device, and
wherein the second lower electrode of the second light-emitting device has an electrical conductivity different from the first lower electrode of the first light-emitting device.

12. The display apparatus according to claim 11, further comprising:
a filter passivation layer on the encapsulation structure; and
a color filter between the encapsulation structure and the filter passivation layer,
wherein the color filter overlaps the first emission area, and
wherein a portion of the filter passivation layer overlapping with the second emission area is in contact with the encapsulation structure.

13. The display apparatus according to claim 11, wherein the second lower electrode has a different thickness from the first lower electrode.

14. The display apparatus according to claim 13, wherein the first lower electrode has a stacked structure of a first electrode layer and a second electrode layer having an electrical conductivity different from the first electrode layer, and
wherein the first electrode layer includes a same material as the second lower electrode.

15. The display apparatus according to claim 11, wherein a planar shape of the second lower electrode is different from a planar shape of the first lower electrode.
